(19) United States
(12) Patent Application Publication
(10) Pub. No.: US 2026/0098912 A1
(43) Pub. Date: Apr. 9, 2026

(54) SYSTEM AND METHOD FOR ASSESSING BATTERY FIRE RISK OF ELECTRIC VEHICLES

(71) Applicant: HEI, Busan (KR)

(72) Inventor: Eunseok LEE, Daegu (KR)

(21) Appl. No.: 19/360,632

(22) Filed: Oct. 16, 2025

Related U.S. Application Data
(63) Continuation-in-part of application No. 19/254,327, filed on Jun. 30, 2025.
Application No. 19/254,327 is a continuation of application No. 18/307,621, filed on Apr. 26, 2023, now Pat. No. 12,345,773.
Application No. 18/307,621 is a continuation-in-part of application No. PCT/KR2022/017998, filed on Nov. 15, 2022.

(30) Foreign Application Priority Data
Nov. 15, 2021 (KR) 10-2021-0156405

(51) Int. Cl. G01R 31/392; G01R 31/367; G01R 31/3842

(52) U.S. Cl. CPC G01R 31/392; G01R 31/367; G01R 31/3842

(57) ABSTRACT

An electric vehicle battery fire risk assessment system includes an information acquisition unit configured to receive real-time vehicle locations from terminals of managed vehicles; a setting unit configured to set State of Health (SOH) risk coefficients based on battery SOH of electric vehicles disposed within a target area that includes a plurality of fire risk assessment points and to set distance correction coefficients based on distances between the electric vehicles and the fire risk assessment points; and a fire risk assessment unit configured to calculate fire risk within the target area using the SOH risk coefficients and distance correction coefficients for the electric vehicles.

### CROSS REFERENCE TO RELATED APPLICATIONS

The present application is a Continuation-in-part of application Ser. No. 19/254,327 filed Jun. 30, 2025, which is a Continuation of application Ser. No. 18/307,621 filed Apr. 26, 2023, which is a Continuation-in-part of International Application No. PCT/KR2022/017998 filed Nov. 15, 2022, which claims priority from Korean Application No. 10-2021-0156405 filed Nov. 15, 2021. The aforementioned applications are incorporated herein by reference in their entireties.

### TECHNICAL FIELD

The present disclosure relates to systems and methods for assessing the fire risk of electric vehicle batteries, and more specifically, for assessing the fire risk of electric vehicle batteries by obtaining the battery SOH (State of Health) and distance information of electric vehicles located in a specific target area based on the real-time locations of target vehicles, and providing the assessed fire risk of electric vehicle batteries in the specific target area.

### RELATED ART

Rechargeable batteries (hereinafter also referred to as “batteries”) are used in a variety of applications, including small electronic devices, such as smart phones, laptop computers and personal digital assistant (PDA), and large-size electric systems, such as electric vehicles and energy storage systems.

Batteries usually deteriorate over time and usage, and as a result, experience performance degradation, such as a decrease in power and capacity, which leads to a degradation of battery performance and failure of applications that operate on the batteries.

The state of health (SOH) of a battery is an indicator that shows how much the battery retains with respect to its initial performance. Since it can be used to determine whether the battery should be replaced, it is important to obtain the SOH accurately for reliable operations of applications.

The SOH is usually estimated by measuring battery parameters, such as maximum capacity, current, voltage, internal resistance and impedance, heat generation rate, peak points in differential capacity curve, and comparing them with their reference values. There are a variety of methods that use different parameters, methods of obtaining them, and methods of integrating and analyzing them. Many efforts are being made to improve existing methods and develop new ones.

With the rapid adoption of electric vehicles, concerns are mounting over fire accidents occurring in various locations such as parking lots, charging stations, and roads. Unlike fires involving conventional vehicles, fires caused by thermal runaway of electric vehicle batteries generate extremely high temperatures and toxic gases, and may trigger chain reactions that cause secondary damage to nearby vehicles and infrastructure.

Currently, fire safety management for electric vehicles mainly depends on monitoring the battery status through individual vehicle battery management systems (BMS) or on fire detection systems implemented at the facility level.

However, these conventional systems are unable to adequately assess the impact of battery State of Health (SOH) on fire risk, nor can they effectively account for the cumulative risk in situations involving multiple vehicles or varying distances between vehicles.

In particular, the risk of fire rises significantly as the battery State of Health (SOH) declines, and the impact on surrounding areas varies depending on the distance when a fire occurs. However, conventional systems are unable to gather such factors from individual or multiple vehicles and to provide integrated risk assessment and management functions that take these factors into account collectively.

Additionally, in areas where multiple electric vehicles are concentrated, the risk levels of individual vehicles interact in complex ways. However, no system currently exists that can monitor these risks in real time and provide users with visualized information.

Therefore, the present disclosure is directed to a system that, based on real-time vehicle locations, utilizes battery State of Health (SOH), distance information, and various environmental factors to assess the fire risk within a target area caused by electric vehicles, monitor the risk in real time, and provide the results in a visualized form.

### SUMMARY

The present disclosure provides new systems and methods for obtaining parameters (e.g., SOH parameters) for SOH estimation and for estimating the SOH based on the SOH parameters. More specifically, current and voltage may be measured during charging, and the generalized fluctuation-dissipation theorem may be applied to the measured current and voltage to obtain the SOH parameters. For each battery model, an SOH model may be developed as a function of SOH parameters and accumulated charge capacity by training based on reference data. The developed SOH model may then be used to estimate and predict the current SOH as well as a future SOH. The results of estimation and prediction may be fed back to the SOH model for iterative improvement and calibration of the model.

An aspect of the present disclosure provides a system that may obtain SOH parameters based on a response function of a battery in the frequency domain, which is obtained from current and voltage fluctuations measured during battery charging, as well as differential capacity and differential voltage curves. This system may also estimate the SOH by tracking changes in the obtained SOH parameters with respect to accumulated charge capacity.

In some embodiments, the system according to the present disclosure may include a database, a parameter processing module, and an SOH estimation module. The database may store current and voltage measurement taken at a specific sampling rate during battery charging, the parameter processing module may obtain a response function of the battery, a differential capacity, and a differential voltage derived from the stored current and voltage data and may derive SOH parameters, and the SOH estimation module may estimate the SOH based on the SOH parameters.

The following features may be included individually or in any combination.

The parameter processing module may obtain the response function of the battery in the frequency domain, based on the Generalized Fluctuation-Dissipation Theorem (GFDT), for each predetermined state of charge (SOC) segment.

The parameter processing module may include a calculation unit, which includes a fluctuation part, an autocorrelation function part, and a response function part. The fluctuation part may obtain, from the database, current fluctuation ΔI(t) during constant current charging (mode I, hereafter), which are defined as the difference of current (I(t)) from the nominal current (I₀(t)), and voltage fluctuation ΔV(t) during constant voltage charging (mode II, hereafter), which are defined as the difference of voltage (V(t)) from the nominal voltage (V₀(t)). The autocorrelation function part may obtain autocorrelation functions for current and voltage fluctuations (C_{I}(t) and C_{V}(t), respectively). The response function part may obtain segmental response functions in the time domain (X(t) and Y(t)) using the following equations, which are then converted to the frequency domain (X′(ω) and Y′(ω)) via the Fourier transform:

$$\{ \begin{matrix}{C}_{I} ( t ) / ( {k}_{B} T ) & t \geq 0 \\ 0 , & t < 0\end{matrix} , Y ( t ) = \{ \begin{matrix}{C}_{V} ( t ) / ( {k}_{B} T ) , & t \geq 0 \\ 0 , & t < 0\end{matrix}$$

where X(t) and Y(t) are the segmental response functions based on the current and voltage fluctuations, respectively, k_{B} is the Boltzmann constant, and T is a temperature.

For each SOC segment, in some embodiments, the autocorrelation function part may divide the data series of the current and voltage fluctuations into a plurality of groups, each having the same sampling rate as the original but having a shorter duration, may obtain the autocorrelation functions for each of the plurality of groups, and may use their average to obtain the (representative) autocorrelation functions for that SOC segment.

For each SOC segment, in some embodiments, the autocorrelation function part may divide the data series of the current and voltage fluctuations into a plurality of groups, each having the same duration as the original but having a lower sampling rate, may obtain the autocorrelation functions for each of the plurality of groups, and may use their average to obtain the (representative) autocorrelation functions for that SOC segment.

The response function part may obtain response functions in the frequency domain X′(ω) and Y′(ω) for each SOC segment (d) and accumulated charge capacity (z) and, thus, eventually as X′(ω,d,z) and Y′(ω,d,z). The parameter processing module may include another calculation unit that obtains the rate of change in capacity with respect to the voltage (differential capacity; dQ/dV) during constant current charging and the rate of change in voltage with respect to the capacity (differential voltage; dV/dQ) during constant voltage charging. dQ/dV and dV/dQ may also be obtained per z and stored in the database to be used as additional SOH parameters. If the resolution of measurement is insufficient to distinguish the voltage fluctuations, dV/dQ may appear to be zero. In this case, the SOH parameters that rely on dV/dQ will be assigned a zero weight as the SOH modeling proceeds.

The SOH estimation module may track changes in the SOH parameters with respect to the accumulated charge capacity to estimate the SOH.

The parameter processing module may calculate X′(ω,d,z)/X′(ω,d,z₀) and Y′(ω,d,z)/Y′(ω,d,z₀), where z₀ indicates an initial charge capacity, the standard deviation of these ratios across ω at each d and z, the similarity of dV/dQ curve between the present and previous charging, and the similarity of dQ/dV curve between the present and previous charging.

The SOH estimation module may apply weights for the SOH parameters, which are stored in and read from the database to the corresponding SOH parameters and may calculate their sum, θ(\tilde{z}), where \tilde{z} is an accumulated charge capacity at the end of each charging session. The sum θ(\tilde{z}) itself or its ratio to θ(\tilde{z}₀) may be used as an indicator for the SOH.

The database may also store the weights of the SOH parameters for each battery model. For each battery model, several sample batteries may be prepared to generate reference data. These batteries may be repeatedly charged and discharged while the SOH parameters are obtained as a function d and z. The SOH may also be obtained as a function of z (SOH^{ref}(z)) by comparing a selected characteristic property, such as full charge capacity, charge capacity within a specific SOC range, internal resistance, etc., to its initial value. While charge capacity within a specific SOC range is used as the characteristic property in the examples provided hereafter, the present disclosure is not limited thereto, and other characteristic properties may also be used.

For each sample battery, the weights of the SOH parameters may be adjusted so that the resultant sum θ(z) of the weighted parameters matches to a reference SOH (SOH^{ref}(z)) for a variety of z. The collection of these adjusted weights may be referred to as an SOH model of the sample battery.

The SOH parameters may be stored in the database and classified by the battery model. The system may further include a reference management module. For each battery model, the reference management module may compare the SOH model across the sample batteries and may examine for anomalies. The SOH models with anomalies may be excluded and the remaining ones may be averaged towards the representative SOH model of that specific battery model. The excluded abnormal SOH models may also be stored in the database in case they later turn out to be other or new battery models.

The estimated SOHs may be stored in the database and classified by the battery model. The system may also include an analysis module, which compares the SOH of a battery with the SOH distribution of other batteries within the same battery model and evaluates that battery. The analysis module may determine that a battery is normal in response to its SOH being within a pre-defined range around the mean SOH of other batteries within the same battery model.

In response to a battery's SOH being outside of the pre-defined normal range, the analysis module may perform further analysis by comparing the values of the battery's SOH parameters with those of other batteries within the same model. In response to an outlier SOH parameter being detected, the analysis module may determine that the battery is not normal.

The SOH estimation module may track changes in the SOH parameters with respect to z, and may predict future behaviors in the SOH parameters and the resultant SOH at future values of z. The analysis module may perform the same analysis for the predicted future SOH as it does for the estimated current SOH. The system may include a notification module, which sends the estimated and predicted SOHs and the analysis result to, for example, users.

The parameter processing module may include a first calculation unit, a second calculation unit, and a post-processing unit. The first calculation unit may obtain the response functions in the frequency domain X′(ω) and Y′(ω) from the current and voltage measurements. The second calculation unit may obtain the differential capacity dQ/dV and the differential voltage dV/dQ. The post-processing unit may obtain the SOH parameters based on all of the results from the first and second calculation units.

The first calculation unit may obtain X′(ω) and Y′(ω) for each SOC segment, based on the generalized fluctuation-dissipation theorem (GFDT).

The post-processing unit may obtain the SOH parameters based on the ratios of X′(ω) and Y′(ω) to their initial values at each frequency, the standard deviation of these ratios, and the similarity of the dQ/dV (and dV/dQ) curves between present and previous charging.

In an aspect of the present disclosure, a method, which the parameter processing module of the system may be configured to perform, may include retrieving the measured current and voltage data from the database, obtaining X′(ω) and Y′(ω) based on the current and voltage data, obtaining differential capacity and differential voltage from the current and voltage data, and obtaining SOH parameters based on the response functions in the frequency domain, the differential capacity, and the differential voltage.

The system according to the present disclosure may obtain a response function of a battery in the frequency domain based on GFDT and may also obtain SOH parameters based on the response function. In particular, the SOH parameters across all frequencies may be retrieved from one continuous measurement of current and voltage during battery charging. Thus, it is not necessary to repeat a process of applying input and measuring output per frequency nor to use additional equipment for such a process, which are usually required for other frequency domain methods, such as electrical impedance spectroscopy.

Also, it is not necessary to narrow the frequency range and identify the frequencies of importance for the frequency range. The system can monitor parameters across the full spectrum of frequency, thereby minimizing the risk of missing important parameters that may emerge later due to chemical changes caused by battery aging.

In practice, the frequency range that can be analyzed may be limited due to discrete measurement of current and voltage. However, such limit can be controlled by adjusting the sampling rate and measurement duration. This adjustment may also be used to selectively remove unnecessary electrical noises in either high or low frequency range, for a more reliable SOH estimation.

In the system, according to the present disclosure, the SOH models may be developed based on changes in the SOH parameters as z varies, and thus the reliability of an SOH model may be improved as more charging data are collected. The system may also collect SOH models and produce a representative SOH model for each battery model, and the reliability of the representative SOH model may be improved as the number of SOH models increases. Thus, the system may predict and control the reliability of representative SOH models and resultant SOH estimation. Also, the SOH and SOH parameters of a battery may be compared with those of other batteries within the same battery model, and the result may be provided to users by the notification module.

The benefits of the present disclosure are not limited to those described above and may be understood throughout this specification.

Another aspect of the present disclosure is to provide a system and method for assessing the fire risk of electric vehicle batteries, in which a battery SOH and distance information of electric vehicles disposed in a specific target area are acquired based on the real-time location information of managed vehicles, and the fire risk within the target area caused by electric vehicle batteries is calculated and provided.

The present disclosure is not limited to the objects described above, and other objects not expressly mentioned herein will be readily understood by those skilled in the art from the following description.

To address the above-mentioned problems, an embodiment of the present disclosure may provide an electric vehicle battery fire risk assessment system, which may include an information acquisition unit configured to receive the real-time location of a vehicle from a terminal of the managed vehicle; a setting unit configured to set an SOH risk coefficient based on the battery SOH of an electric vehicle located within a target area including multiple fire risk assessment points, and to set distance correction coefficients based on the distance between the fire risk assessment points and the electric vehicle; and a fire risk assessment unit configured to calculate the fire risk within the target area using the SOH risk coefficients and distance correction coefficients.

Furthermore, an embodiment of the present disclosure may provide an electric vehicle battery fire risk assessment method, which includes a step of receiving the real-time location of a vehicle from a terminal of the managed vehicle; a step of setting an SOH risk coefficient based on the battery SOH of an electric vehicle disposed within a target area including multiple fire risk assessment points; a step of setting distance correction coefficients based on the distance between the fire risk assessment points and the electric vehicle; and a step of calculating the fire risk within the target area using the SOH risk coefficients and distance correction coefficients.

The specific details of other embodiments are set forth in the detailed description and drawings.

The electric vehicle battery fire risk assessment system and method according to the embodiments of the present disclosure may acquire the battery SOH and distance information of electric vehicle batteries located within a specific target area based on the real-time locations of managed vehicles, and calculate and provide the fire risk in the target area caused by the electric vehicles using the acquired information.

Accordingly, the system can monitor in real time the changes in fire risk caused by changes in the locations of electric vehicles or their entry into and exit from the target area, and users can check the fire risk corresponding to their own location, the location of their vehicle, or a pre-set target area.

Furthermore, when multiple electric vehicles are present within this target area, the individual fire risk levels of the vehicles may be aggregated to calculate the overall fire risk in the target area, and this information may be provided in a visual form (e.g., a fire risk map with distinct contour lines by grade), enabling users and managers to quickly recognize the fire risk level according to their location within the target area.

The effects of the present disclosure are not limited to those described above, and other effects will be readily understood by those skilled in the art from the following description.

### BRIEF DESCRIPTION OF THE DRAWINGS

FIG. 1 is a diagram illustrating an electric vehicle battery fire risk assessment system according to an embodiment of the present disclosure.

FIG. 2 is a block diagram illustrating the schematic configuration of the electric vehicle battery fire risk assessment server of FIG. 1.

FIG. 3 is a flowchart illustrating an electric vehicle battery fire risk assessment method according to an embodiment of the present disclosure.

FIG. 4 is a fire risk map (contour lines) of a target area according to an embodiment of the present disclosure.

FIG. 5 schematically shows an embodiment of a system for battery SOH estimation, as well as other relevant elements, according to embodiments of the present disclosure.

FIG. 6 is a block diagram that shows the structure of the system in more detail.

FIG. 7 is a block diagram that shows the structure of another embodiment of the system.

FIG. 8 is a block diagram that shows the structure of the first calculation unit shown in FIG. 6 and FIG. 7.

FIGS. 9-11 show graphs that explain two noise reduction techniques that may be employed by the autocorrelation function part.

FIGS. 12 and 13 show graphs that explain parameters that can be obtained from the parameter processing module shown in FIG. 5 and FIG. 7.

FIG. 14 is a block diagram that shows another embodiment of the system.

FIG. 15 is an example of the notification module in FIG. 14.

FIG. 16 is a flow diagram that explains the procedure for SOH estimation according to the embodiment shown in FIG. 6 and FIG. 7.

FIG. 17 is a flow diagram that shows the procedure for SOH estimation according to the embodiment shown in FIG. 14.

### DETAILED DESCRIPTION

The advantages and features of the present disclosure, and methods of achieving them, will become apparent upon reference to the embodiments described in detail with reference to the accompanying drawings. However, the disclosure is not limited to the embodiments disclosed herein. The present disclosure can be embodied in many different forms, and these embodiments are provided merely to make the disclosure complete and to fully inform one of ordinary skill in the art to which the disclosure belongs, and the disclosure is defined by the scope of the claims.

The dimensions and relative sizes of the components shown in the drawings may be varied for clarity of description. Throughout the specification, like reference numerals refer to like components, and “and/or” includes each and every combination of one or more of the items mentioned.

The terminology used in this specification is intended to describe embodiments and is not intended to limit the disclosure. As used herein, singular forms also include plural forms unless the context clearly requires otherwise. The words “comprises” and/or “comprising” as used in the specification do not exclude the presence or addition of one or more other components in addition to those mentioned.

Although the terms “first,” “second,” and the like are used to describe various devices or components, such devices or components are not limited by such terms. These terms are used merely to distinguish one element or component from another, so that a first element or component referred to herein may also be a second element or component within the technical idea of the present disclosure.

Unless otherwise defined, all terms (including technical and scientific terms) used in this specification are intended to be used in the sense in which they would be understood by one of ordinary skill in the technical field to which the present disclosure belongs, and commonly used dictionary definitions are not to be construed as idealized or over-interpreted unless expressly defined as such.

The following detailed description is not intended to be limiting, and the scope of the disclosure is limited only by the appended claims, which, when properly described, encompass all the equivalents of what is claimed therein. In the drawings, like reference numerals refer to the same or similar features in various aspects.

Hereinafter, the disclosure will be presented in detail with reference to embodiments and drawings, which are intended to help readers to better understand the disclosure, not to limit the scope thereof. The disclosure may be embodied in various forms.

The fire hazard of electric vehicle batteries is determined by factors such as the high heat, flammable gases, and flame spread released during thermal runaway, and the severity of the hazard varies significantly with distance.

Furthermore, the battery SOH, an important factor in evaluating batteries, is directly associated with various degradation phenomena, such as increased internal resistance and reduced charge/discharge capacity, as its value decreases.

In view of these points, various embodiments of the present disclosure may analyze the fire risk of electric vehicle batteries based on SOH and distance, in order to calculate the fire risk level in a specific target area.

The electric vehicle battery fire risk assessment system according to embodiments of the present disclosure can calculate the fire risk caused by at least one electric vehicle located in a specific target area, thereby enabling assessment and management of the fire risk within the target area.

In addition, by providing the fire risk level for the target area where the managed vehicle is located, or for a target area designated by the user or manager of the managed vehicle, to a request terminal, the system may enable monitoring, managing, and preventing fire risks caused by electric vehicles in the target area.

In this case, the target area may include any spatial region where vehicles can move or be located, such as parking lots, gas stations, and roads.

Furthermore, the managed vehicles may include electric vehicles, hybrid vehicles, and the like, and may be vehicles registered in a terminal (such as a user terminal or a vehicle terminal) of a service application that provides the fire risk level of electric vehicles in a specific target area.

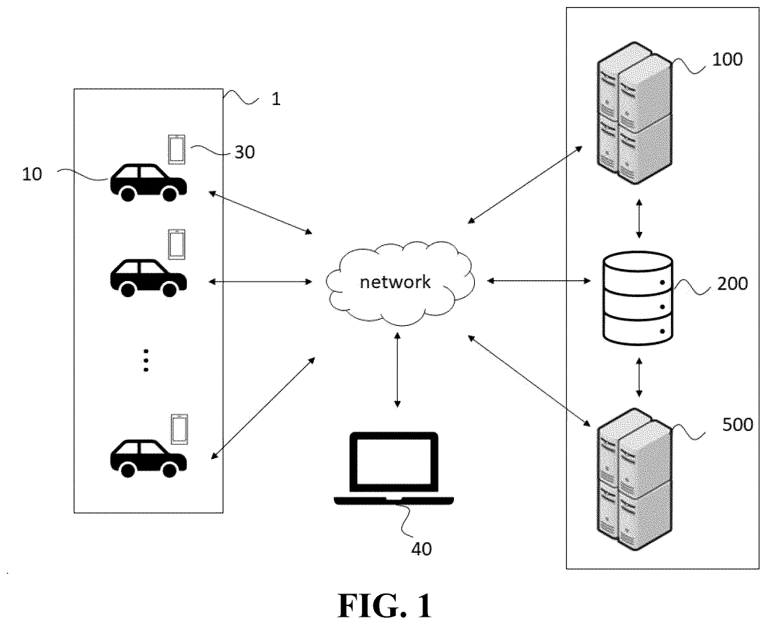

Accordingly, the electric vehicle battery fire risk assessment system according to various embodiments of the present disclosure will be described in detail with reference to FIGS. 1 to 17.

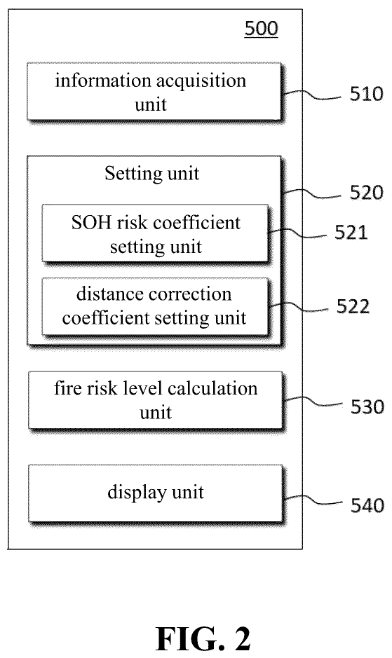

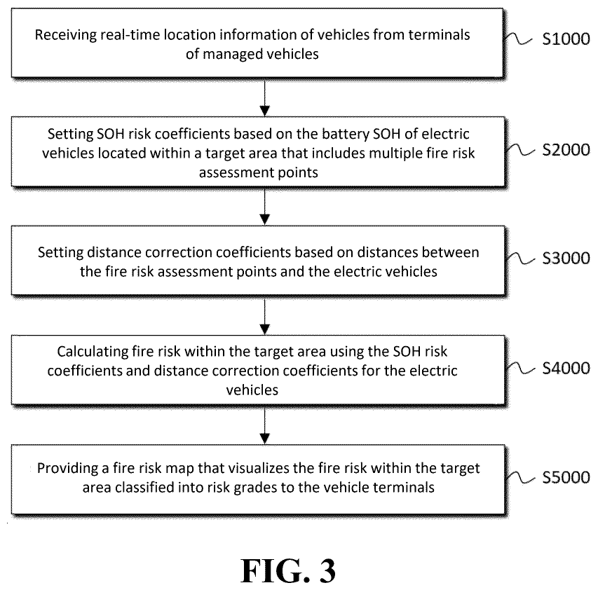

FIG. 1 is a diagram illustrating an electric vehicle battery fire risk assessment system according to an embodiment of the present disclosure. FIG. 2 is a block diagram illustrating the schematic configuration of the electric vehicle battery fire risk assessment server shown in FIG. 1. FIG. 3 is a flowchart illustrating an electric vehicle battery fire risk assessment method according to an embodiment of the present disclosure.

Referring to FIGS. 1 and 2, the electric vehicle battery fire risk assessment system according to the present disclosure may include a fire risk assessment server 500 and a database 200, and may further include an State-of-Health (SOH) estimation server 100. In this case, the SOH estimation server 100, the database 200, and the fire risk assessment server 500 may each be configured as an independent system, server, or module.

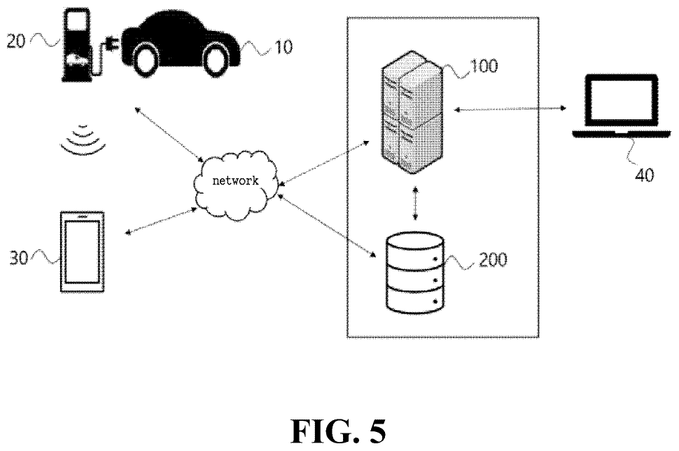

The SOH estimation server 100 receives the charging current and voltage of registered electric vehicles during charging and estimates the SOH based on variations in the charging current and voltage of the vehicle battery. The estimated SOH of the vehicle battery may be stored in the database 200 and updated each time charging occurs. The specific functions and operations of the SOH estimation server 100 are described in FIG. 5.

The database 200 stores and manages data generated during information exchange with managed vehicles 10, the SOH estimation server 100, and other components. It supplies the information required for SOH estimation to the SOH estimation server 100, and the information required for fire risk assessment to the fire risk assessment server 500.

The database 200 may also store real-time location information received from each managed vehicle, current and voltage data received during charging of the managed electric vehicles, and the SOH of each electric vehicle estimated by the SOH estimation server 100. In addition, information on each managed vehicle and its terminal 30 may be stored in a matched manner.

Here, the vehicle terminal 30 refers to a user terminal on which a service application providing the fire risk level of electric vehicles in a specific target area according to an embodiment of the present disclosure is installed and may correspond to a terminal installed in the vehicle or a terminal such as a user's smartphone.

Referring to FIG. 2, the electric vehicle battery fire risk assessment server 500 may include an information acquisition unit 510, a setting unit 520 comprising an SOH risk coefficient setting unit 521 and a distance correction coefficient setting unit 522, a fire risk level calculation unit 530, and a display unit 540. Each component may be configured as an independent server or module. In addition, the server 500 may further include a UI provision unit (not shown) that provides a user interface for receiving requests for target area settings and fire risk information from the vehicle terminal 30.

The electric vehicle battery fire risk assessment server 500 receives a request from the vehicle terminal 30 to provide fire risk information for a target area, or, when the application is executed by the user, the server can obtain the real-time location of the vehicle from the vehicle terminal 30 through the information acquisition unit 510 for real-time target area setting. At this time, the received real-time vehicle location may be stored in the database 200 in real time and then accessed by the information acquisition unit 510, or may be directly received by the information acquisition unit 510 in real time and subsequently stored in the database 200.

The functions and operations of each component will be described in detail in conjunction with the flowchart of FIG. 3.

The information acquisition unit 510 can receive the real-time location of the target vehicle from the vehicle terminal of the managed vehicle (S1000). Additionally, the information acquisition unit 510 can receive the battery SOH of the electric vehicle from the vehicle terminal 10 or extract the SOH stored in the database 200. In other words, the information acquisition unit 510 can obtain the real-time locations of the managed vehicles, determine the positions of the electric vehicles in each target area based on the real-time locations, and thereby acquire the battery SOH of the electric vehicles.

Here, the target area is a space where vehicles can move and stop, and includes multiple fire risk assessment points. The target area may be divided into multiple zones according to the fire risk assessment points.

For example, when the target area is a parking lot, the parking lot may be divided into multiple grids, and each grid point or the center point of each grid may serve as a fire risk assessment point within the target area. For extensive areas such as highways, the target area can be divided into multiple areas, and adjacent upstream and downstream sections can be set as a single target area. Furthermore, the target area can be defined based on a predefined radius range according to the real-time location of vehicles.

In other words, the target area may be a predefined fixed area (such as a parking lot or a highway divided into multiple target areas), or it may be a variable area set according to the real-time movement of vehicles within a predefined radius range. Additionally, it may be a specific area designated by users or administrators through their respective apps or terminals.

This is just one example, and the division of target areas and the setting of multiple fire risk assessment points within the target area can be implemented in various ways.

The SOH risk coefficient setting unit 521 can set the SOH risk coefficient based on the battery SOH (State of Health) of the electric vehicle located within the target area that includes multiple fire risk assessment points (S2000). Generally, the lower the SOH, the higher the fire risk. Therefore, in this disclosure, the risk coefficient increases as the SOH decreases.

In other words, the SOH risk coefficient setting unit 521 sets SOH risk coefficients for each predefined SOH range, assigning higher coefficients to lower SOH ranges. Additionally, the SOH risk coefficient setting unit 521 may generate and utilize a table (e.g., Table 1 below) that maps SOH ranges to SOH risk coefficients Wₛ.

TABLE 1

| SOH Range | SOH Risk Coefficient |
|---|---|
| 100%-81% | 1 |
| 80%-71% | 3 |
| 70% or below | 5 |

For example, based on Table 1, if the battery SOH of an electric vehicle located in the target area is 85%, the SOH risk coefficient may be 1. Additionally, the SOH risk coefficient setting unit 521 can incorporate various SOH-related values—such as the average value and recent value of the SOH, the degradation rate (e.g., monthly reduction rate), and the average and recent values of the degradation rate—along with other SOH-related parameters, to generate a matching table (e.g., Table 2 below). The final risk coefficient may also be calculated by summing the weighted values of the risk coefficients assigned to each evaluation item.

TABLE 2

| | SOH Risk | SOH Risk | SOH Risk |
|---|---|---|---|
| Evaluation Item | Coefficient 1 | Coefficient 3 | Coefficient 5 |
| SOH Range | 100%-81% | 80%-71% | 70% or less |
| SOH Degradation | Less than 1.0 | 1.0-2.5 | Greater than 2.5 |
| Rate (%/month) | | | |
| Average SOH | 85% or higher | 75%-84% | 74% or less |
| (3 months) | | | |
| Recent SOH | Less than 3% | 3%-8% | Greater than 8% |
| Variation (1 month) | | | |

Meanwhile, the classification ranges of the risk coefficients for each evaluation item in Tables 1 and 2 may be subject to change.

Additionally, the distance correction coefficient setting unit 522 can establish distance correction coefficients based on the distance between each fire risk assessment point and the electric vehicle (S3000). At this time, the distance correction coefficient setting unit 522 can calculate the distance correction coefficient using the recommended distance for the electric vehicle—preset according to vehicle type—and the actual distance between each fire risk assessment point included in the target area and the location of the electric vehicle.

At this time, the vehicle type may be, for example, a bus, passenger car, or truck, and the recommended distance may be a safe separation distance required to prevent fire spread and casualties in the event of a fire, depending on the vehicle type.

Additionally, the recommended distance may be determined by various environmental factors that influence the fire hazard intensity for each vehicle type, such as the ambient temperature around the target area, the distance the heat emitted from the battery during thermal runaway can reach, the amount of thermal energy emitted, the flame spread distance depending on the battery size, and the combustibility depending on the presence of cargo.

In an embodiment of the present disclosure, the recommended distance according to vehicle type may be preset, for example, 4 meters for passenger cars and 6 meters for buses and trucks.

Additionally, the actual distance may be defined as the physical distance from each predefined fire risk assessment point within the target area to the real-time location of the electric vehicle.

The distance correction coefficient setting unit 522 can calculate the distance correction coefficient W_{d} based on Equation 1 below. However, if the actual distance to a fire risk assessment point is greater than the recommended distance, the distance correction coefficient may be set to 1.

$${W}_{d} = {( Recommended distance / Actual distance )}^{2} \qquad Equation 1$$

Additionally, the fire risk calculation unit 530 can calculate the fire risk within the target area using the SOH risk coefficient Wₛ of the electric vehicle's battery and the distance correction coefficient W_{d} (S4000). More specifically, the fire risk Rᵢ for each electric vehicle can be calculated based on the following Equation 2. Here, the fire risk represents the fire risk score that the electric vehicle imposes on its surroundings.

$${R}_{i} = {W}_{s} \times {W}_{d} \qquad Equation 2$$

That is, the fire risk assessment unit 530 can calculate the fire risk Rᵢ for each electric vehicle at the fire risk assessment point by multiplying the SOH risk coefficient Wₛ of the vehicle's battery and the distance correction coefficient Wd. Meanwhile, the calculation of the distance correction coefficient in Equation 1 and the calculation of the fire risk level in Equation 2 are merely examples and are not limited thereto; various other methods may also be used.

Additionally, when multiple electric vehicles are present within the target area, the fire risks caused by each vehicle can be summed to determine the overall fire risk within the target area. For example, consider the following scenario where electric vehicles A and B are located within the target area:
Vehicle A: Passenger car, SOH=85%, Actual distance=5 m, Recommended distance=4 m
Vehicle B: Vehicle type unknown, SOH=70%, actual distance=2 m, recommended distance=4 m (assumed to be the shortest Recommended distance among all vehicle types due to the unknown vehicle type)

In this case, referring to Table 1, since the battery SOH of Vehicle A is 85%, the SOH risk coefficient Wₛ is set to 1. Because the actual distance (5 m) is greater than the recommended distance (4 m) for Vehicle A, the distance correction coefficient Wd can be set to 1 without adjustment. Therefore, the fire risk level R₁ for Vehicle A can be 1.

Additionally, since the battery SOH of Vehicle B is 70%, the SOH risk coefficient Wₛ is set to 5. Because the actual distance (2 m) is shorter than the recommended distance (4 m) for Vehicle B, the distance correction coefficient Wd can be set to 4 based on Equation 1. Therefore, the fire risk level R₂ for Vehicle B can be 20.

Therefore, the total fire risk level Rtotal in the target area is the sum of R₁ and R₂, resulting in 21. This example illustrates the case where two vehicles are located in the target area. When multiple (n) electric vehicles are present, the fire risk levels caused by each of the n vehicles can be summed to calculate the total fire risk level of the target area.

The display unit 540 can provide a fire risk map that visually categorizes the fire risk within the target area into risk grades to the vehicle terminals (S5000). Specifically, the display unit 540 divides the fire risk level within the target area calculated by the fire risk calculation unit 530 into predefined ranges to set risk grades, and visualizes this information as a fire risk map or a similar format, providing it to the terminals 30 of the managed vehicles and the administrator terminals 40.

For example, the fire risk map may be visualized with contour lines of different colors corresponding to risk grades, together with the locations of the electric vehicles within the target area. As an example, the categorization can be made as shown in Table 3 below.

TABLE 3

| Fire Risk Level in | | |
|---|---|---|
| Target Area (Rₜₒₜₐₗ) | Risk Grade | Response Measures |
| 0-5 | Safe | Normal operation possible |
| 6-15 | Caution | Visual warning, caution alert |
| 16 or higher | Danger | Alarm triggered, access |
| | | restriction measures |

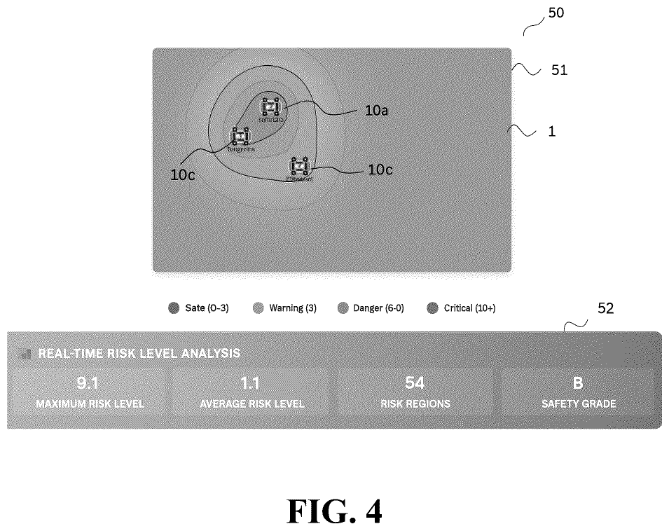

Meanwhile, FIG. 4 shows a fire risk map (contour lines and color gradation) of the target area according to an embodiment of the present disclosure. Referring to FIG. 4, the fire risk information 50 provided through the display unit 540 may include a fire risk map 51 visualized with contour lines for the target area 1, and numerical real-time hazard analysis information 52. In FIG. 4, the risk level is divided into four grades, and the fire risk map of the target area 1 is visualized based on the risk analysis of each electric vehicle 10a, 10b, and 10c when three electric vehicles are located in the target area 1.

Additionally, the analysis information for the target area 1 provides maximum risk level, average risk level, number of risk zones, and risk grade (safety grade), enabling monitoring of the fire risk situation in the target area 1.

Furthermore, the system can display information such as the SOH and location of each electric vehicle, along with the location of the vehicle terminal, on the fire risk map. In this case, if the vehicle is an electric vehicle, it is displayed as one of the electric vehicles on the fire risk map, and if it is a non-electric vehicle, its location is displayed in a manner distinguishable from electric vehicles.

Accordingly, the terminal 30 of the managed vehicle and the manager terminal 40 receive information as shown in FIG. 4 to recognize the fire risk situation in the target area 1. Through the terminal, real-time fire risk information of the target area where the vehicle is located can be provided, and users can search for a specific location they intend to move to and check the fire risk information of the target area in advance. In cases where the risk level increases sharply, immediate warning notifications are provided to enable proactive response.

Meanwhile, FIGS. 5 to 17 illustrate embodiments for estimating the SOH of electric vehicles among the managed vehicles. The information acquisition unit 510 of the fire risk assessment server 500 according to the present embodiment receives the real-time location of the managed vehicle 10 from the terminal 30 of the managed vehicle, and receives the SOH of an electric vehicle among the managed vehicles 10 from the terminal 30 of the electric vehicle, or extracts the SOH estimated for the electric vehicle from the database 200 by the SOH estimation server 100. The SOH risk coefficient setting unit 521 sets the SOH risk coefficient based on the extracted SOH of the electric vehicle, thereby enabling calculation of the fire risk level for the target area according to FIGS. 1-4.

According to the present disclosure, various state of health (SOH) parameters may be obtained, and the SOH of batteries may be estimated based on the obtained SOH parameters. The following embodiments explain SOH estimation for electric vehicle (EV) batteries; however, application of the present disclosure is not limited to EV batteries, and it may be applied to any batteries for other devices and systems.

A battery may typically comprise a cathode, an anode, one or more separators, electrolyte, SEI layer, contacts, etc., and these components, especially their material properties and integration, deteriorate over time and during charging-discharging cycles, which may result in the degradation of performance and safety.

In a battery, the dynamic characteristics of charge carriers such as ions and electrons are largely dependent on the surrounding chemical environment. As the battery materials and their integration deteriorate, the chemical environment surrounding the charge carriers changes, causing a change in the dynamic characteristics of the charge carriers and consequently causing changes in a response function of the battery in response to the externally applied electrical current or voltage. Accordingly, the level of deterioration of the battery materials and their integration may be estimated by measuring the change in the response function of the battery.

According to the present disclosure, such parameters that can capture changes in the response function of a battery may be obtained, and the SOH of the battery may be evaluated based on the SOH parameters. In addition, other parameters relevant to differential capacity and differential voltage may also be obtained and employed as additional SOH parameters.

One of the well-known methods for obtaining the electrical response function of a battery is Electrical Impedance Spectroscopy (EIS); however, it requires consumption of relatively large amounts of energy and time.

More specifically, to perform the EIS, an input (electrical) signal is applied to a system of interest at a specific frequency, and the corresponding output signal is measured. Then the ratio of the output signal to the input signal is defined as the response at that specific frequency, and the response function is obtained by collecting the responses while varying the frequency. As such, a process of input application and output measurement is needed and should be repeated for every frequency of interest.

In particular, for an EV battery, the frequency of interest spans over several orders of magnitude, typically from 10 mHz to 1 kHz. Repeating the process of applying an AC input and measuring an AC output may cost a substantial amount of time and electric energy. One way to reduce the cost is to decrease the number of frequencies of interest by finding the important frequencies that correspond to the most dominant dynamic characteristics of charge carriers. However, this may cause a problem if the purpose of the EIS is to capture the change in the dynamic characteristics of charge carriers, because such important frequencies may be changed as the most dominant dynamic characteristics of charge carriers change later due to the change of surrounding chemical environment. In addition, the EIS requires a separate process and a device or equipment for carrying out the EIS.

The present disclosure provides a more efficient way to obtain a response function of a battery based on current and voltage during charging, which are measured by default for metering the amount of charged energy, controlling the charging process, monitoring, and detecting battery problems such as overvoltage and overcurrent. As such, unlike the EIS method, there is no additional and repetitive process for data collection.

In the present disclosure, a response function of a battery may be obtained by employing the generalized fluctuation-dissipation theorem (GFDT), and its components may be used in the frequency domain as primary parameters for the SOH estimation. The fluctuation-dissipation theorem (FDT) is a theory for predicting the behavior of a system. For a system under an equilibrium state, the FDT states that a response of the system to an external perturbation can be estimated by thermodynamic fluctuations in physical variables. The GFDT provides that the FDT can be applied to a system in a more generalized non-equilibrium state, especially when a system is in steady state, by additionally considering entropic terms.

The present disclosure leverages the fact that batteries are commonly charged in non-equilibrium steady states, which satisfies the necessary conditions for applying the GFDT. It employs the GFDT to obtain a response function of a battery, based on current and voltage measurements taken during the charging. This response function is subsequently used to derive parameters related to the SOH of the battery. The following embodiments provide details of systems and methods for obtaining the response function of a battery, deriving SOH parameters from the response function, and estimating the SOH based on the SOH parameters in combination with other parameters based on differential quantities.

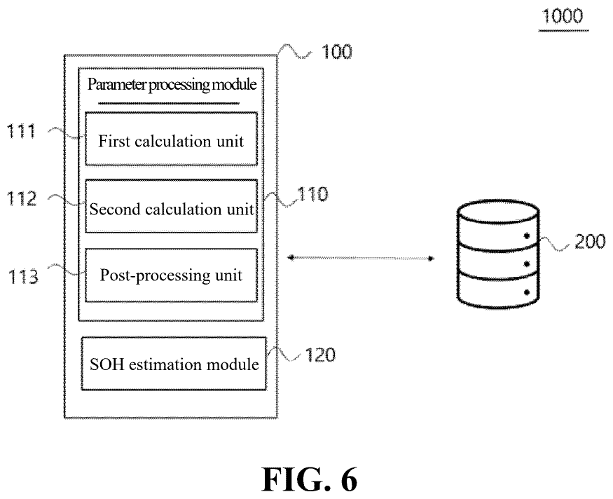

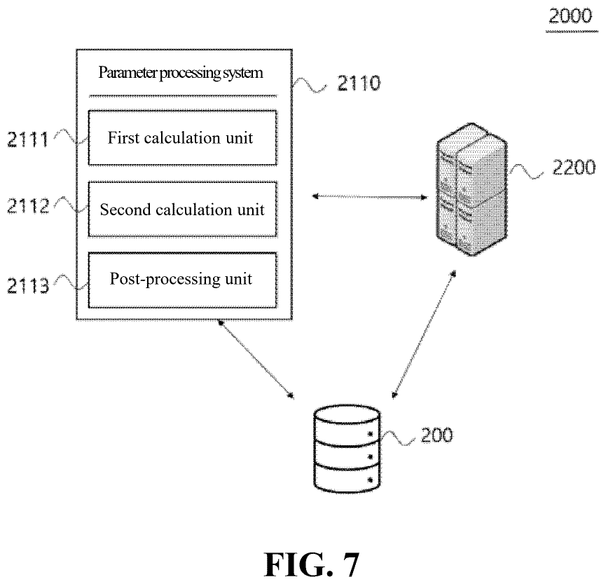

FIG. 5 shows an embodiment of the system for battery SOH estimation (enclosed by a rectangle) and other relevant elements. FIG. 6 is a block diagram that shows the structure of the system shown in FIG. 5 in more detail. FIG. 7 is a block diagram that shows the structure of another embodiment of the system.

Referring to FIG. 5, the system according to an embodiment of the present disclosure may include a server computer 100 and a database 200. The server computer 100 may include a parameter processing module 110 and an SOH estimation module 120 as shown in FIG. 6 or it may include a parameter processing system 2110 and an SOH estimation system 2200 as shown in FIG. 7.

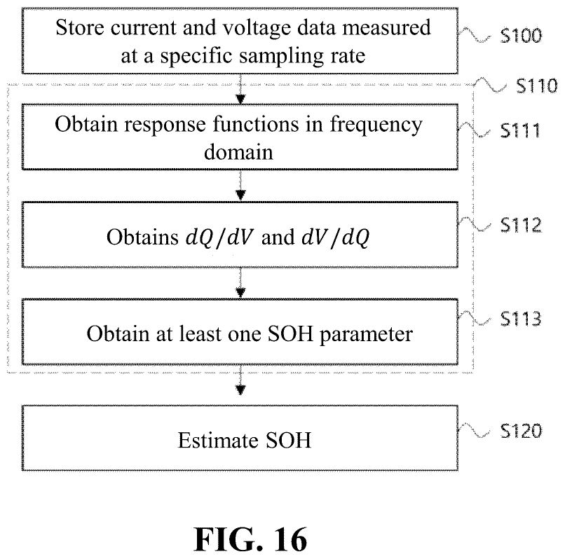

The parameter processing module 110 and the SOH estimation module 120 in FIG. 6 may have equivalent functions and structures to the parameter processing system 2110 and the SOH estimation system 2200 in FIG. 7. Thus, hereinbelow, explanations will be given based on the structure shown in FIG. 6 in conjunction with the method shown in FIG. 16.

As seen in FIG. 6, the system 1000 may include a server computer 100 and a database 200. The server computer 100 may be equipped with the parameter processing module 110 and the SOH estimation module 120. The parameter processing module 110 may include two calculation units, namely, a first calculation unit 111 and a second calculation unit 112, and a post-processing unit 113.

During the charging of an EV 10, electric current and voltage may be measured with a charger 20, the EV 10, or a separate metering device. The system in the embodiment may receive the measured data from either user's smartphone 30 or a charging service provider.

Where the user's smartphone 30 is used, the smartphone 30 may receive the current and voltage data measured by the charger 20, the EV 10, or the metering device, and may transmit the received data to the server computer 100.

The database 200 of the system, which is operatively connected to the server computer 100, may store the current and voltage data measured at a specific sampling rate (S100; see FIG. 16). In some embodiments, the database 200 may be implemented as a cloud server, which is physically separated from the server computer 100 but still connected online.

The user's smartphone 30 may collect information about the user and the EV (e.g., vehicle model, battery model, or the like) and transmit it to the database 200 where the information is stored. This information may be used to match the current and voltage data measured during the charging with the corresponding battery so that the data can be tracked on a per-battery basis.

The parameter processing module 110, which is a part of the system 100, may obtain SOH parameters (S110) based on the received current and voltage data. Step S110 may also be a method for deriving the parameter adopted by the parameter processing system 2110.

The first calculation unit 111 may obtain response functions in the frequency domain using the current and voltage data stored in the database 200 for each state of charge (SOC) segment (S111).

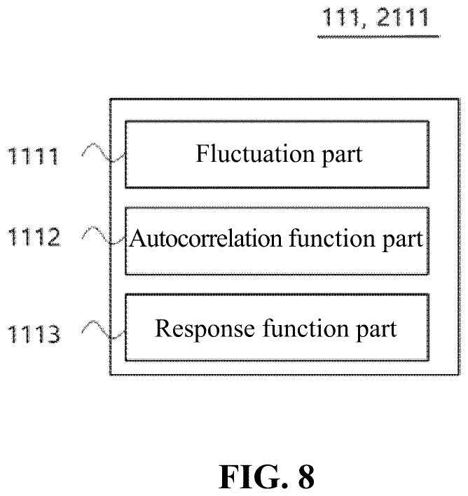

FIG. 8 is a diagram that shows the structure of the first calculation unit 111 in FIG. 6 and the first calculation unit 2111 in FIG. 7. More specifically, the first calculation unit 111 may include three calculation parts, namely, a fluctuation part 1111, an autocorrelation function part 1112, and a response function part 1113, respectively.

The fluctuation part 1111 may include two operating modes, for obtaining current fluctuation during constant current charging (mode I), which is defined as the deviation of current (I(t)) from nominal current (I₀(t)), and for obtaining voltage fluctuation during constant voltage charging (mode II), which is defined as the deviation of voltage (V(t)) from nominal voltage (V₀(t)), respectively. Accordingly, current fluctuations ΔI(t)=I(t)−I₀(t) may be obtained in mode I, and voltage fluctuations ΔV(t)=V(t)−V₀(t) may be obtained in mode II.

In general, EV batteries are charged with constant current (CC) up to about 80% SOC and with constant voltage (CV) beyond about 80% SOC.

In this embodiment, the response function of a battery may be obtained differently depending on whether the battery is being charged in CC or CV mode. Thus, the fluctuation part 1111 may operate in mode I for CC charging and mode II for CV charging.

The autocorrelation function part 1112 may obtain autocorrelation functions for current fluctuations (C_{I}(t)) and voltage fluctuations (C_{V}(t)). Here, the autocorrelation function part 1112 may apply the following noise reduction techniques based on the frequency range corresponding to important characteristics of batteries.

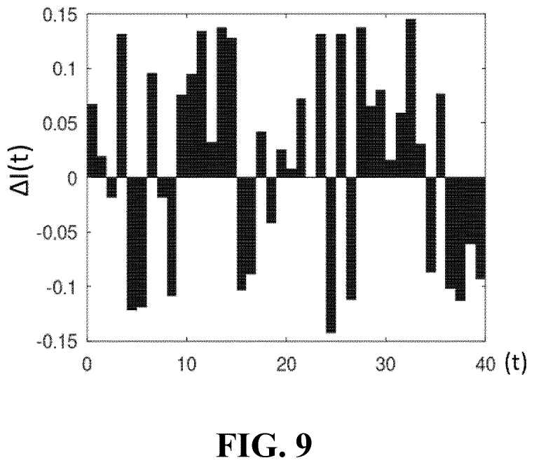

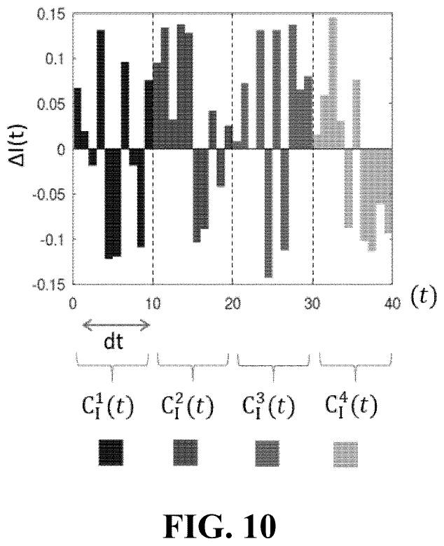

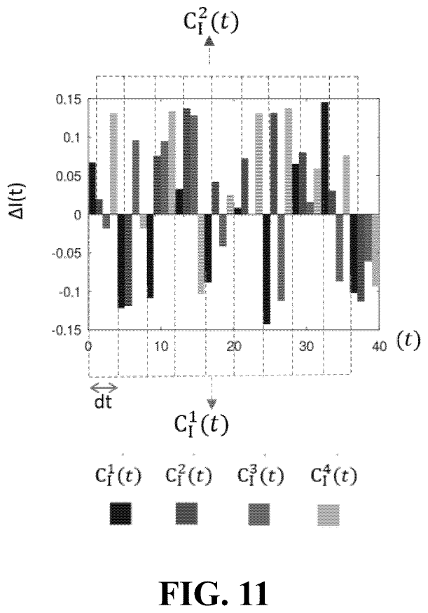

FIGS. 9-11 explain two noise reduction techniques that may be employed in the autocorrelation function part 1112 for current fluctuations ΔI(t). Substantially same techniques may be applied to voltage fluctuations ΔV(t). FIG. 9 is an example of current fluctuations ΔI(t) calculated by the fluctuation part 1111, while FIG. 10 and FIG. 11 demonstrate the first and the second noise reduction techniques, respectively, applied to the current fluctuations in FIG. 9.

In the first noise reduction technique (FIG. 10), the data series of current fluctuations ΔI(t) in an SOC segment may be divided into shorter (e.g., smaller) pieces by dividing the data series in sequence by a specific length (e.g. 4 pieces, each with the length of 10 in FIG. 10), and the autocorrelation function may be calculated for each piece

$$( {C}_{I}^{1} ( t ) , {C}_{I}^{2} ( t ) , {C}_{I}^{3} ( t ) , and {C}_{I}^{4} ( t ) ) .$$

All of the resultant autocorrelation functions may be averaged to obtain the autocorrelation function for the SOC segment

$$( {C}_{I} ( t ) = ( {C}_{I}^{1} ( t ) + {C}_{I}^{2} ( t ) + {C}_{I}^{3} ( t ) + {C}_{I}^{4} ( t ) ) / 4 ) .$$

In the second noise reduction technique (FIG. 11), the data series of current fluctuations (ΔI(t)) in an SOC segment may be divided into shorter pieces (e.g., segments) of a predetermined length (e.g., 4 pieces, each with the length of 10 in FIG. 11). These pieces may be constructed by re-sampling the data series at the rate of the number of pieces while varying the initial sampling point of each piece. Then, the autocorrelation function may be calculated for each piece

$$( {C}_{I}^{1} ( t ) , {C}_{I}^{2} ( t ) , {C}_{I}^{3} ( t ) , and {C}_{I}^{4} ( t )$$

in FIG. 11). In the case of FIG. 11, the

$${C}_{I}^{1} ( t )$$

may be the autocorrelation function calculated for the data series sampled at t=0, t=4, . . . , t=36, the

$${C}_{I}^{2} ( t )$$

may be the autocorrelation function calculated for the data series sampled at t=1, t=5, . . . , t=37, and so on. All of the resultant autocorrelation functions may be averaged to obtain the autocorrelation function for the SOC segment

$$( {C}_{I} ( t ) = ( {C}_{I}^{1} ( t ) + {C}_{I}^{2} ( t ) + {C}_{I}^{3} ( t ) + {C}_{I}^{4} ( t ) ) / 4$$

### in FIG. 11).

For a more detailed example, let us assume a data series of fluctuations ΔI(t) and ΔV(t) with time step dt and 1000*dt duration in an SOC segment and assume that we desire to divide SOC segment into 10 pieces. In case of the first noise reduction technique, the first piece may include the data sampled at t=0, 1*dt, . . . , 99*dt, the second piece may include the data sampled at t=100*dt, 101*dt, . . . , 199*dt, and so on. In case of the second noise reduction technique, the first piece may include the data sampled at t=0, 10*dt, 20*dt, . . . , 990*dt, the second piece may include the data sampled at t=1*dt, 11*dt, 21*dt, . . . , 991*dt, the third piece may include the data sampled at t=2*dt, 12*dt, 22*dt, . . . , 992*dt and so on. That is, each piece may be composed of 100 data points in either technique.

When the first noise reduction technique is applied, the resultant autocorrelation function may retain the same time step as the original data series, but covers a shorter duration, thereby preserving the information in a high frequency range. When the second noise reduction technique is applied, the resultant autocorrelation function may cover the same duration as the original data series, but with a longer time step, thereby preserving the information in a low frequency range. Thus, the frequency range of interest, over which the characteristics of batteries is the most dominant, should be considered to decide whether these noise reduction techniques will be applied and, if applied, which one will be.

When batteries are being charged, the charger measures current and voltage at a specific sampling rate to ensure that they are controlled and maintained at the intended values. These data can be transmitted to the database for use by the system of the present disclosure. Additionally or alternatively, the present disclosure may also use a metering device as another channel to obtain the current and voltage. The metering device may have a sampling rate that is equal to or faster than the sampling rate of the charger.

The time step, dt, may be determined considering several factors. Certain battery characteristics may appear more prominently at specific frequencies, which can cause inefficiencies in data storage, management, and transmission if the sampling rate is set too high across the entire charging process. For example, if one parameter requires data to be sampled at a 0.1 second interval and another parameter can be adequately captured at a 10 second interval, it would be inefficient to maintain a high sampling rate (e.g., 0.1 second interval) throughout the entire charging process. The present disclosure provides varying the sampling rate flexibly. In the case of the example above, the time interval may be maintained at 0.1 seconds for a specific duration and then reset to 10 seconds for the remaining period of measurement once sufficient information has been gathered. The timing for resetting the sampling rate should be determined through a pre-examination.

According to the FDT and GFDT, for a system in equilibrium, a response function of a system to external perturbations is proportional to the correlation function between the fluctuations in relevant physical variables, observed without the perturbations. For a system in a non-equilibrium state, a correction term may be added to the response function.

The autocorrelation function part 1112 may obtain autocorrelation functions C_{I}(t)= [symbol] ΔI(t);ΔI(t) [symbol] and C_{V}(t)= [symbol] ΔV(t);ΔV(t) [symbol] for current and voltage fluctuations, respectively.

The response function part 1113 may obtain response functions X(t) and Y(t) using the following Equation 3 and may further apply the Fourier Transform to obtain response functions in the frequency domain (X′(ω) and Y′(ω)).

$$X ( t ) = \{ \begin{matrix}{C}_{I} ( t ) / ( {k}_{B} T ) , & t \geq 0 \\ 0 , & t < 0\end{matrix} , Y ( t ) = \{ \begin{matrix}{C}_{V} ( t ) / ( {k}_{B} T ) , & t \geq 0 \\ 0 , & t < 0\end{matrix} \qquad Equation 3$$

where X(t) and Y(t) are response functions based on current and voltage fluctuations (ΔI(t) and ΔV(t)), respectively. k_{B} is the Boltzmann constant, and T is the internal temperature of battery.

With respect to the battery temperature, the present disclosure considers that battery charging typically begins when the corresponding EV arrives at the charging station, and the battery usage gradually decreases as the EV approaches the charging station. Reference data may be collected at different charging speeds to account for changes in SOH parameters that may occur due to corresponding differences in heat generation.

In addition, the present disclosure is based on utilizing the ratios of SOH parameters at present to their initial values, not the absolute values of the response functions. Thus, the impact of temperature is not explicitly addressed in the present disclosure.

However, the parameters at zero frequency may correspond to the responses related to a DC current and DC voltage and thus may be deemed to change proportionally or inverse proportionally to internal resistance. Based on this idea, the impact of temperature may be included in the SOH modeling indirectly. More specifically, internal resistance may be measured for a battery in an early fresh stage by varying the temperature and then its temperature coefficient of resistance may be pre-determined by using the relationship, R=R₀(1+α(T−T₀)), where T is the temperature, T₀ is the reference temperature, R is the internal resistance, R₀ is the internal resistance at the reference temperature, and α is the temperature coefficient of resistance.

Then, assuming that the chance for significant variation of the internal resistance between two adjacent charging events is low except due to the temperature, the temperature of battery may be estimated based on the change in the parameter at zero frequency and be reflected on the process to obtain the response functions.

As a battery is being charged, the chemical environment around charge carriers may change, causing the battery's response functions to vary. Thus, when comparing response functions, it may be necessary to consider the SOC and compare only those obtained at a similar SOC.

For that purpose, the maximum capacity of a battery may be divided into even-sized SOC segments (e.g., at 10% SOC increment). When a battery is being charged, the SOC segments corresponding the measured current and voltage may be identified, and X′(ω) and Y′(ω) may be obtained for each SOC segment. The size of SOC segment may be determined considering the statistics about EV drivers' charging habits and the data sampling capability of measurement devices (i.e., chargers or metering devices).

Also, the accumulated charge capacity at the end of each SOC segment may be calculated and may serve as a variable of the response functions in the frequency domain, such as X′(ω,d,z) and Y′(ω,d,z), where d is the index of SOC segment and z is the accumulated charge capacity.

In the present disclosure, the accumulated charge capacity may be defined in two different ways: at the end of each SOC segment (z) or at the end of each charging event (\tilde{z}). For example, if the accumulated charge capacity was 100 kWh in the previous charging and 47 kWh was charged in the present charging, the \tilde{z} becomes 147 kWh.

Further, the response functions for the SOC segments, e.g. in case of 10% increment, 0-10% (d=1), 10-20% (d=2), 20-30% (d=3), and 30-40% (d=4) will have at z=110, 120, 130, and 140, respectively, and the one for 40-50% (d=5) SOC segment will have z=147.

In the present disclosure, both definitions of accumulated charge capacity may be used.

Specifically, the response functions in the frequency domain may be obtained per an SOC segment and z (X′(ω,d,z) and Y′(ω,d,z)), stored in the database 200, and transmitted to the post-processing unit to be used for obtaining SOH parameters (functions of z) and an SOH indicator (a function of \tilde{z}).

The second calculation unit 112 may obtain the differential capacity (dQ/dV) during constant current charging and differential voltage (dV/dQ) during constant voltage charging from the current and voltage measured at a specific sampling rate (S112 in FIG. 16). The dQ/dV and dV/dQ may also be obtained per z and may be stored in the database 200.

The post-processing unit 113 may obtain at least one SOH parameter based on the response functions obtained from the first calculation unit 111 and dQ/dV and dV/dQ from the second calculation unit 112 (S113 in FIG. 16).

At least one SOH parameter may correspond to the ratio of the response function's value to the initial value at each frequency, the standard deviation of these ratios at different frequencies, or the similarity of dQ/dV (and dV/dQ) curve between the present and previous charging.

### SOH Parameters for Battery SOH Estimation

1) The ratio of the response function based on current fluctuations to its initial value: Φ(ω,d,z)

A type of SOH parameter Φ_{X}(ω,d,z) may be defined as the ratio of the response function in the frequency domain based on the current fluctuation (X′(ω,d,z)) to its initial value

$$( {X}_{i n i}^{′} ( ω , d , z ) ) , i . e . , {Φ}_{X} ( ω , d , z ) = {X}^{′} ( ω , d , z ) / {X}_{i n i}^{′} ( ω , d , z ) ,$$

at specific frequency ω, SOC segment label d, and accumulated charge capacity z.

2) The ratio of the response function based on voltage fluctuations to its initial value: Φ_{Y}(ω,d,z)

A type of SOH parameter Φ_{Y}(ω,d,z) may be defined as the ratio of the response function in the frequency domain based on the voltage fluctuation (Y′(ω,d,z)) to its initial value

$$( {Y}_{i n i}^{′} ( ω , d , z ) ) , i . e . , {Φ}_{Y} ( ω , d , z ) = {Y}^{′} ( ω , d , z ) / {Y}_{i n i}^{′} ( ω , d , z ) ,$$

at specific frequency w, SOC segment label d, and accumulated charge capacity z.

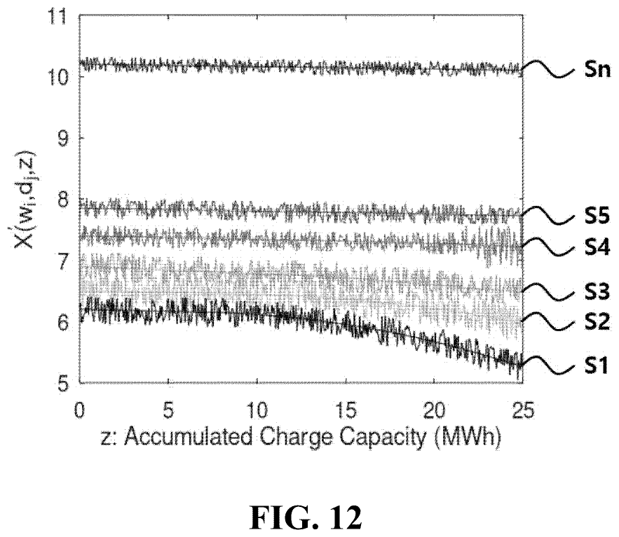

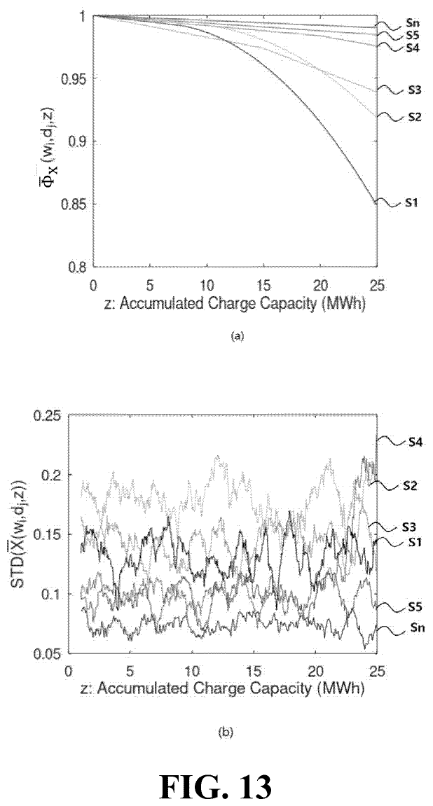

FIG. 12 shows several examples for X′(ω,d,z) with noise. The curves may be used after being smoothed out, with the noise removed. Panel (a) of FIG. 13 shows the normalized curves after the noise removal from the curves in FIG. 12, and panel (b) of FIG. 13 shows the standard deviation of each curve in FIG. 12 over a specific period of z.

More specifically, Φ_{X}(ω,d,z) and Φ_{Y}(ω,d,z) with noise as shown in FIG. 12 may be fitted to typical functions such as linear, polynomial, exponential, logarithmic functions, or combinations thereof, after the accumulated charging qualifies a minimum amount required for the fitting (e.g., corresponding to 5 full charges). The fitted results may be referred to as Φ̅_{X}(ω,d,z) and Φ̅_{Y}(ω,d,z) and may be used instead of Φ_{X}(ω,d,z) and Φ_{Y}(ω,d,z).

3) A standard deviation of the response function in the frequency domain based on current fluctuations: σₓ(ω,d,z)

The response function in the frequency domain based on the current fluctuations (X′(ω,d,z)) may be obtained and collected for a specific range of accumulated charge capacity (z_{sd}). The standard deviation of these collected X′(ω,d,z) may be defined as an SOH parameter σ_{X}(ω,d,z)=SD{X′(ω,d,z−z_{sd}˜z)}.

4) A standard deviation of the response function in the frequency domain based on voltage fluctuations: σ_{Y}(ω,d,z)

The response function in the frequency domain based on the voltage fluctuations (Y′(ω,d,z)) may be obtained and collected for a specific range of accumulated charge capacity (z_{sd}). The standard deviation of those collected Y′(ω,d,z) may be defined as an SOH parameter σ_{Y}(ω,d,z)=SD{Y′(ω,d,z−z_{sd}˜z)}.

When z is less than z_{sd} for an SOC segment, σ_{X}(ω,d,z) and σ_{y}(ω,d,z) may be defined as the standard deviations of X′(ω,d,z) and Y′(ω,d,z) collected for the entire z range of that SOC segment, respectively.

5) The similarity of dQ/dV curve between present and previous charging: μ_{dQ/dV}(\tilde{z})

6) The similarity of dV/dQ curve between present and previous charging: μ_{dV/dQ}(\tilde{z})

The similarities of dQ/dV and dV/dQ compared with those in the previous charging may be obtained by using Dynamic Time Warping Method.

That is, the similarities of dQ/dV and dV/dQ between two adjacent charging events may be used as SOH parameters, instead of the absolute values of dQ/dV and dV/dQ at a specific SOC. dQ/dV and dV/dQ curves for a specific SOC range may be used, instead of those for the entire SOC range.

The SOH estimation module 120 may use all or some of the SOH parameters to estimate the SOH based on their changes (S120).

SOH parameters multiplied by their weights may be summed to derive Θ(\tilde{z}) using the following Equation 4, and the SOH may be estimated based on the ratio of Θ(\tilde{z}) to its value at the initial charging (Θᵣ) using the following Equation 5.

$$Θ ( \tilde{z} ) = {\sum }_{i , j} {h}_{i , j} {Φ}_{X} ( {ω}_{i} , {d}_{j} , z ) + {\sum }_{k , l} {h}_{k l} {Φ}_{Y} ( {ω}_{k} , {d}_{l} , z ) + {\sum }_{p , q} {h}_{p q} {σ}_{X} ( {ω}_{p} , {d}_{q} , z ) + {\sum }_{r , s} {h}_{r s} {σ}_{Y} ( {ω}_{r} , {d}_{s} , z ) + {h}_{v} {μ}_{d Q / d V} ( \tilde{z} ) + {h}_{w} {μ}_{d V / d Q} ( \tilde{z} ) \qquad Equation 4$$

where hᵢⱼ, hₖₗ, h_{pq}, hᵣₛ, hᵥ, and h_{w} are the weights of the corresponding SOH parameters.

$${Θ}_{r} ( \% ) = \frac{Θ ( \tilde{z} )}{Θ ( {\tilde{z}}_{INI} )} \times 100 \qquad Equation 5$$

where Θ(\tilde{z}) is the sum of the weighted SOH parameters, and Θ(\tilde{z}ᵢₙᵢ) is the SOH parameter at the initial charging. The initial charging may refer to the first effective charging.

The term ‘effective charging’ may refer to a charging session that exceeds approximately 30% of the nominal capacity of the battery. This value is selected tentatively to include data from charging in the constant current (CC) mode for at least 10% of the nominal capacity, as the charging process usually proceeds up to 80% SOC in the CC mode. When a different charging profile is used, a different value may be selected.

The SOH estimation module 120 may obtain the Θᵣ using Eq. 3 and use it to estimate the SOH. The weights of SOH parameters may be obtained from the database.

The weights of SOH parameters may be adjusted based on reference data. The reference data are a collection of charging data (current and voltage measured during battery charging) under pre-defined charging conditions, or a more extended collection of the charging data from multiple batteries of the same battery model. Whenever new charging data are obtained from existing batteries or new batteries, they may be added to the reference data.

Once the weights of the SOH parameters have been adjusted, they may be stored in the database and used by the SOH estimation module for SOH estimation. The SOH estimation module may apply the adjusted weights to the corresponding SOH parameters using Equations 2 and 3 to obtain Θᵣ. Thus obtained Θᵣ may then be used to estimate the SOH directly or relatively. As more data are added to the reference data, the weights of SOH parameters may need to be adjusted continuously. Thus, it may be effective to include a separate monitoring system dedicated to tracking changes in the reference data and updating the weights of the SOH parameters on a regular basis. This process may continue until the reference data reach a sufficient level of diversity.

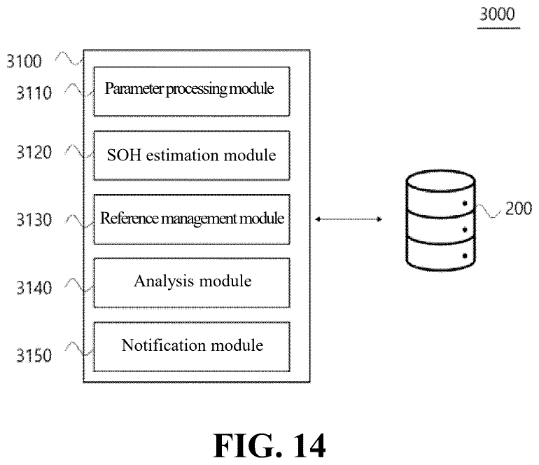

The methods for adjusting the weights of SOH parameters and estimating SOH directly and relatively will be explained in more detail referring to the embodiment shown in FIG. 14.

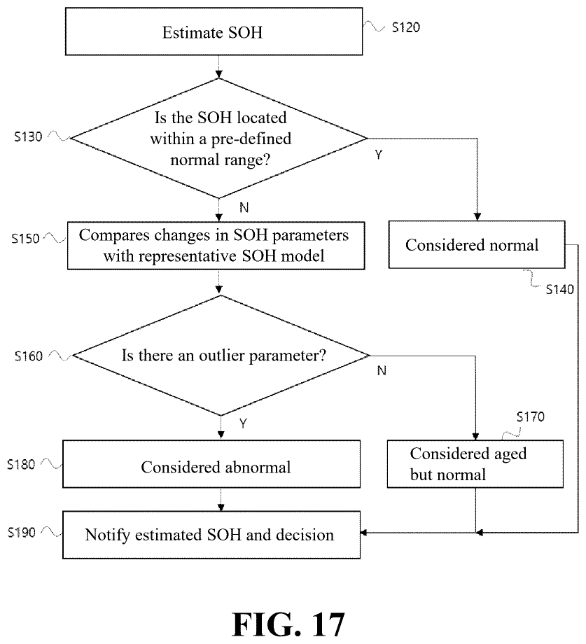

FIG. 14 shows another embodiment of the system, which includes a reference management module 3130, an analysis module 3140, and a notification module 3150, in addition to the components of the embodiments shown in FIG. 6 and FIG. 7. A parameter processing module 3110 and an SOH estimation module 3120 may have substantially the same functions as the parameter processing module 110 in FIG. 6 and the parameter processing system 2110 in FIG. 7, respectively. The SOH estimation module 3120 may perform additional functions that may be required to estimate the SOH either directly or relatively. The SOH estimation system in FIG. 14 can be explained along with the SOH estimation method in FIG. 17.

The parameter processing module 3110 may obtain SOH parameters, and the SOH estimation module 3120 may obtain the Θᵣ using Equation 5 and may use it to estimate the SOH directly and relatively. The weights of SOH parameters may be adjusted and managed by the reference management module 3130.

### Estimating SOH Directly

In the present disclosure, estimating the SOH directly may mean that the value of Θᵣ itself serves as the SOH.

To estimate the SOH of an EV battery, SOH parameters may be obtained based on the charging data collected during the battery charging. The SOH estimation module 3120 may then read the weights of the SOH parameters for the same EV battery model from the database 200 and may apply them to the SOH parameters using Equation 4. Here, the weights of the SOH parameters may have been adjusted based on reference SOHs, which have been collected as a part of the reference data.

As previously explained, the reference data may be collected by repeatedly charging one or more sample batteries within a specific SOC range using various charging conditions but within a safe range.

At the end of each charging session, a reference SOH may be defined as the ratio of the charging capacity within the specific SOC range to the initial value. This definition of reference SOH is based on a widely accepted industry standard for tracking capacity change. Other SOH definitions, such as internal resistance change, peak voltage shift, etc., may be considered in other embodiments. SOH parameters may also be obtained using the charging data, and their weights may be obtained by adjusting them to minimize the discrepancy between the Θᵣ and the reference SOH. The adjusted weights may be stored in the database to be used by the SOH estimation module.

The reference data may be expanded up to 200-300 charging sessions or until problematic cases are detected. The number of charging sessions may vary depending on battery models.

The reliability of the reference data may be improved by increasing the number of sample batteries. It may also shorten the time needed to detect problematic cases.

### Estimating SOH Relatively

The SOH estimation module 3120 may obtain the SOH in a relative manner. Reference data may be collected from batteries operated under various conditions including ideal and harsh conditions. The Θᵣ in Equation 5 may be obtained for each operating condition and used as the reference Θᵣs. The SOH of an EV battery may then be estimated by comparing its Θᵣ with the reference Θᵣs.

Specifically, the weights of SOH parameters may be adjusted to allow Θᵣs for the best and the worst cases to become 100% and 0%, respectively, and Θᵣs for intermediate cases to be between 0% and 100%. Once adjusted, the weights may be applied to the corresponding SOH parameters of the EV battery using Equation 4, to estimate its SOH. Since the reliability of this approach largely depends on the diversity of batteries included in the reference data, battery operating conditions may be arranged so that they can well-reflect various conditions that batteries can experience. A group of batteries may be operated under ideal conditions, such as slow charging within a safe SOC range with a nominal buffer, sufficient rest time between charging and subsequent discharging, operation at a constant and slow rate, and room temperature, etc., to maintain the batteries' original state longer. On the other hand, other group of batteries may be operated under harsh conditions, such as steep changes in charging and discharging rates, operating in extreme temperatures, frequent fast charging, full or over-charging and -discharging, etc., to degrade the batteries rapidly.

Reasoning behind the relative SOH estimation is that batteries operated under ideal conditions may age mildly and experience less degradation, while batteries operated under harsh conditions may degrade rapidly, resulting in a poorer SOH. As more diverse data from batteries of the same model are added, the reliability of SOH estimation may be improved.

The database 200 may store the SOH parameters and the obtained SOH as a function of accumulated charge capacity, for each battery model.

The reference management module 3130 may examine the developed SOH models of batteries for anomalies, and if any anomalies exist, those models may be excluded from further process. The remaining models may be weighted and averaged to create a representative SOH model. The weights of SOH parameters may be continuously updated as the reference data set grows, and as a result, the representative SOH model may also be updated over time.

The analysis module 3140 may compare the SOH of a battery to the distribution of SOHs for the same battery model with a similar value of z, to determine if the SOH falls within a pre-defined normal range. More specifically, in response to the SOH being within a pre-defined normal range (S130:Y) compared to the average SOH for the same type of EV battery model (the representative SOH), the battery may be determined to be normal (S140). In response to the SOH being outside of the pre-defined normal range (S130:N), the battery may then be subjected to additional analysis to determine its state and potential issues.

Specifically, the values of the SOH parameters may be compared with those used in the representative model. In response to the changes in the SOH parameters with respect to the accumulated charge capacity being consistent with the behavior of the representative SOH model, the battery may be determined to have been aged but still operating normal (S170). However, when one or more parameters behave significantly differently from the representative SOH model, the parameters may be examined for inconsistency with the reference model.

An outlier may be defined as a parameter deviation from the representative SOH model, expressed as a ratio (e.g., ±20%) of the parameter in the representative SOH model. This ratio may vary depending on the battery model.

In other words, the analysis module 3140 may compare (S150) the changes in the SOH parameters with the SOH parameters of the representative SOH model. If there is an outlier parameter (S160:Y), the battery may be determined to be abnormal (S180). If there is no outlier parameter, the battery may be considered aged but normal (S170).

In some embodiments, in response to outlier parameters being consistently detected over a few charging sessions, the system may send an alert to user's smartphone 30.

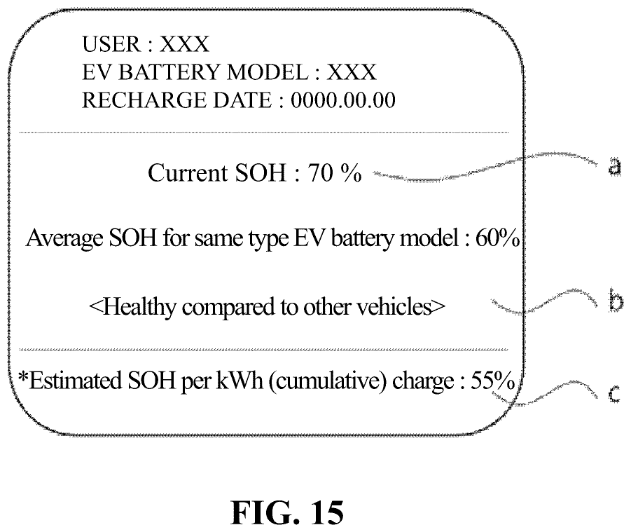

The notification module 3150 may provide the SOH estimated by the SOH estimation module 3120 and the decision made by the analysis module 3140 by sending a ‘push’ message (S190). For example, as shown in FIG. 15, users may receive the SOH (a) and the analysis result (b) on their smartphones 30.

The SOH estimation module 120 and 3120 may predict a battery's future SOH based on the past SOH estimates. Specifically, the changes in the SOH parameters with respect to the accumulated charge capacity may be tracked, and their tendency may be formulated as a typical function such a polynomial function, an exponential function, or the like. Then, the values of the SOH parameters at a specific future point in time and the resultant SOH may be predicted. The notification module 3150 may then provide the predicted information to the users for planning battery replacement.

The future point in time may be indicated by the users or administrators (e.g., managers or operators, which may be persons or machines) in terms of the additional accumulated charge capacity beyond the present. Thus, it should be greater than the accumulated charge capacity at present.

All of the data and results, including the current and voltage data, response functions, dQ/dV, dV/dQ, SOH parameters, estimated SOH, and analysis result, may be stored in the database 200 and may also be provided to system administrator's terminal as numerical values and/or figures.

Therefore, by extracting parameters from response functions in the frequency domain based on the Generalized Fluctuation-Dissipation Theorem (GFDT), the need for additional equipment such as electrical impedance spectroscopy instruments can be eliminated, thereby reducing both time and power consumption. Furthermore, parameters can be obtained simultaneously across the entire frequency range, and by comprehensively utilizing multiple parameters, a more accurate estimation of the battery's State of Health (SOH) can be achieved.

The SOH estimated for each electric vehicle in this manner can be updated in real time, enabling the calculation of fire risk posed by electric vehicles within the target area based on this information.

Accordingly, the electric vehicle fire risk assessment system and method, according to various embodiments of the present disclosure, can acquire the SOH and distance information of electric vehicles located in a specific target area based on the real-time positions of managed vehicles, and can calculate and provide the fire risk posed by electric vehicles within that specific target area using this information.

As such, fire risk—changing in real time due to vehicle movement or entry/exit within the target area—can be continuously monitored, and users can check the fire risk level in the target area corresponding to the location of their own vehicles.

Furthermore, when multiple electric vehicles are present within the target area, the individual fire risk levels of each vehicle are aggregated to compute the overall fire risk of the area. This risk level is presented in a visual format—such as a fire risk map with clearly segmented contour lines—allowing users and managers to quickly identify the spatial distribution of fire risk within the target area. In some embodiments, the users and/or managers may relocate some or all of the vehicles to mitigate the overall fire risk of the area. In some embodiments, the users and/or managers may proactively guide the drivers of the entering vehicles in a way that minimizes the overall fire risk of the area.

The various embodiments of the present disclosure may be combined with one another to form new embodiments.

The electric vehicle fire risk assessment system according to various embodiments of the present disclosure may include an information acquisition unit that receives real-time vehicle locations from terminals of managed vehicles, a setting unit that sets SOH (State of Health) risk coefficients based on the SOH of electric vehicles disposed within a target area that includes multiple fire risk assessment points and sets distance correction coefficients based on the distance between the electric vehicles and each fire risk assessment point, and a fire risk assessment unit that calculates the fire risk within the target area using the SOH risk coefficients and distance correction coefficients for the electric vehicles.

In another aspect of the present disclosure, the setting unit sets SOH risk coefficients for each predefined SOH range, such that the SOH risk coefficient is set to a higher value as the SOH of the electric vehicle decreases.

In another aspect of the present disclosure, the setting unit may calculate the distance correction coefficient using the recommended distance for the electric vehicle based on preset recommended distances for each vehicle type and the actual distance between the real-time location of the electric vehicle and each fire risk assessment point.

In another aspect of the present disclosure, the setting unit calculates the distance correction coefficient based on the following mathematical formula:

$$distance correction coefficient = {( recommended distance / actual distance )}^{2}$$

In response to the actual distance to each fire risk assessment point being greater than the recommended distance, the distance correction coefficient can be set to 1.

In another aspect of the present disclosure, the fire risk assessment unit calculates the fire risk caused by the electric vehicle at each fire risk assessment point, and the fire risk can be calculated by multiplying the SOH risk coefficient for the electric vehicle by the distance correction coefficient.

In another aspect of the present disclosure, the fire risk assessment unit calculates the fire risk caused by at least one electric vehicle disposed within the target area, and the fire risk within the target area may be the sum of the fire risks caused by each electric vehicle.

In another aspect of the present disclosure, the system may further include a display unit that provides a fire risk map to the terminal of the corresponding vehicle, wherein the fire risk map visualizes the fire risk within the target area classified into risk grades.

In another aspect of the present disclosure, the fire risk map may include contour lines of different colors corresponding to the locations of electric vehicles and risk grades within the target area.

In another aspect of the present disclosure, the system further includes a database that stores SOH estimated for each electric vehicle based on voltage and current during charging of electric vehicles among the managed vehicles, and the information acquisition unit can extract SOH for at least one electric vehicle disposed within the target area from the database or receive it from the terminal of the corresponding electric vehicle based on the real-time locations of the managed vehicles.

The electric vehicle fire risk assessment method according to various embodiments of the present disclosure may include a reception step of receiving real-time vehicle locations from terminals of managed vehicles, a coefficient setting step that sets SOH (State of Health) risk coefficients based on the SOH of electric vehicles disposed in a target area that includes multiple fire risk assessment points and sets distance correction coefficients based on the distance between the electric vehicles and each fire risk assessment point, and a fire risk assessment step that assesses the fire risk within the target area using the SOH risk coefficients and distance correction coefficients for the electric vehicles.

In another aspect of the present disclosure, the coefficient setting step sets SOH risk coefficients for each predefined SOH range, such that the SOH risk coefficient is set to a higher value as the SOH of the electric vehicle decreases.

In another aspect of the present disclosure, the coefficient setting step may calculate the distance correction coefficient using the recommended distance for the electric vehicle based on preset recommended distances for each vehicle type and the actual distance between the real-time location of the electric vehicle and each fire risk assessment point.

In another aspect of the present disclosure, the coefficient setting step calculates the distance correction coefficient based on the following mathematical formula:

$$distance correction coefficient = {( recommended distance / actual distance )}^{2}$$

In response to the actual distance from each fire risk assessment point being greater than the recommended distance, the distance correction coefficient can be set to 1.

In another aspect of the present disclosure, the fire risk assessment step calculates the fire risk caused by the electric vehicle at each fire risk assessment point, and the fire risk can be calculated by multiplying the SOH risk coefficient for the electric vehicle by the distance correction coefficient.

In another aspect of the present disclosure, the fire risk assessment step calculates the fire risk caused by at least one electric vehicle disposed within the target area, and the fire risk within the target area may be the sum of the fire risks caused by each electric vehicle.

In another aspect of the present disclosure, the method may further include a display step of providing a fire risk map to the terminal of the corresponding vehicle, wherein the fire risk map visualizes the fire risk within the target area classified into risk grades.

In another aspect of the present disclosure, the fire risk map may include contour lines of different colors corresponding to the locations of electric vehicles and risk grades within the target area.

In another aspect of the present disclosure, the method further includes a step of obtaining SOH for at least one electric vehicle disposed within the target area from a database or from the terminal of the corresponding electric vehicle based on the real-time locations of the managed vehicles, wherein the database stores SOH estimated for each electric vehicle based on voltage and current during charging of electric vehicles among the managed vehicles.

The units, modules, or components described in the server-client system of the present disclosure may be implemented on the server side, client side, or both sides for system efficiency, performance optimization, and load balancing. The specific locations and implementation methods of such units, modules, or components may be determined at the discretion of those skilled in the art and do not limit the scope of the present disclosure. Therefore, even if a specific unit, module, or component is described as being located on the server side or client side in the embodiments described herein, this is merely illustrative, and the actual implementation may be arranged differently as needed.

Embodiments of the present disclosure have been described in more detail with reference to the accompanying drawings, but the present disclosure is not necessarily limited to these embodiments and may be practiced in various modifications without departing from the technical ideas of the present disclosure. Accordingly, the embodiments disclosed herein are intended to only illustrate and not to limit the technical ideas of the disclosure, nor the scope of the technical ideas of the disclosure. Therefore, the embodiments described above should be understood to be exemplary and non-limiting in any respect. The scope of protection of the present disclosure shall be construed in accordance with the following claims, and all technical ideas within the scope thereof shall be construed to be included in the scope of the present disclosure.

What is claimed is:

1. An electric vehicle fire risk assessment system comprising:
an information acquisition unit configured to receive real-time location information of vehicles from terminals of managed vehicles;
a setting unit configured to:
(i) set a State of Health (SOH) risk coefficient based on battery SOH of electric vehicles disposed in a target area including a plurality of fire risk assessment points; and
(ii) set a distance correction coefficient based on distances between the electric vehicles and the respective fire risk assessment points; and
a fire risk assessment unit configured to calculate a fire risk within the target area using the SOH risk coefficient and the distance correction coefficient for the electric vehicles.

2. The system of claim 1, wherein the setting unit is configured to set SOH risk coefficients for each predefined SOH range, such that the SOH risk coefficient is set to a higher value as the battery SOH of the electric vehicle decreases.

3. The system of claim 1, wherein the setting unit is configured to calculate the distance correction coefficient based on:
(i) a recommended distance preset for each vehicle type; and
(ii) an actual distance between a real-time location of the electric vehicle and each fire risk assessment point.

4. The system of claim 3, wherein the setting unit is configured to calculate the distance correction coefficient according to the following formula:
$$Distance Correction Coefficient = {( Recommended Distance / Actual Distance )}^{2} ,$$
and to set the distance correction coefficient to 1 in response to the actual distance to any fire risk assessment point being greater than the recommended distance.

5. The system of claim 1, wherein the fire risk assessment unit is configured to calculate a fire risk caused by each electric vehicle at each fire risk assessment point by multiplying the SOH risk coefficient by the distance correction coefficient.

6. The system of claim 1, wherein the fire risk assessment unit is configured to calculate a fire risk caused by at least one electric vehicle disposed within the target area, and
wherein the fire risk within the target area is calculated as a sum of fire risks caused by each electric vehicle.

7. The system of claim 1, further comprising a display unit configured to provide a fire risk map to the terminals of the vehicles, wherein the fire risk map visualizes the fire risk within the target area classified into risk grades.

8. The system of claim 7, wherein the fire risk map includes contour lines of different colors corresponding to locations of electric vehicles and risk grades within the target area.

9. The system of claim 1, further comprising a database configured to store estimated battery SOH values for electric vehicles, the SOH values being estimated based on voltage and current during charging of electric vehicles among the managed vehicles,
wherein the information acquisition unit is further configured to obtain a battery SOH for at least one electric vehicle disposed within the target area based on real-time location information, either by retrieving it from the database or by receiving it from a terminal of the electric vehicle.

10. A method for assessing electric vehicle fire risk, the method comprising:
receiving real-time location information of vehicles from terminals of managed vehicles;
setting a State of Health (SOH) risk coefficient based on battery SOH of electric vehicles disposed within a target area including a plurality of fire risk assessment points;
setting a distance correction coefficient based on distances between the electric vehicles and the respective fire risk assessment points; and
calculating a fire risk within the target area using the SOH risk coefficient and the distance correction coefficient for the electric vehicles.

11. The method of claim 10, wherein setting the SOH risk coefficient comprises setting SOH risk coefficients for each predefined SOH range, such that the SOH risk coefficient is set to a higher value as the battery SOH of the electric vehicle decreases.

12. The method of claim 10, wherein setting the distance correction coefficient comprises calculating the distance correction coefficient based on:
(i) a recommended distance preset for each vehicle type; and
(ii) an actual distance between a real-time location of the electric vehicle and each fire risk assessment point.

13. The method of claim 12, wherein setting the distance correction coefficient comprises calculating the distance correction coefficient according to the following formula:
$$Distance Correction Coefficient = {( Recommended Distance / Actual Distance )}^{2} ,$$
and setting the distance correction coefficient to 1 in response to the actual distance to any fire risk assessment point being greater than the recommended distance.

14. The method of claim 10, wherein calculating the fire risk comprises calculating a fire risk caused by the electric vehicle at each fire risk assessment point by multiplying the SOH risk coefficient by the distance correction coefficient.

15. The method of claim 10, wherein calculating the fire risk comprises calculating a fire risk caused by at least one electric vehicle disposed within the target area, and
wherein the fire risk within the target area is calculated as a sum of the fire risks caused by each electric vehicle.

16. The method of claim 10, further comprising providing a fire risk map to the terminals of the vehicles, wherein the fire risk map visualizes the fire risk within the target area classified into risk grades.

17. The method of claim 16, wherein the fire risk map includes contour lines of different colors corresponding to locations of electric vehicles and risk grades within the target area.

18. The method of claim 10, further comprising obtaining a battery SOH for at least one electric vehicle disposed within the target area based on real-time location information, the battery SOH being obtained from a database or from a terminal of the electric vehicle,
wherein the database is configured to store estimated battery SOH values for electric vehicles, the estimation being based on voltage and current during charging of electric vehicles among the managed vehicles.
